(19) United States
(12) Patent Application Publication
(10) Pub. No.: US 2025/0212557 A1
(43) Pub. Date: Jun. 26, 2025

(54) METHOD FOR MANUFACTURING LIGHT-EMITTING DEVICE

(71) Applicant: Nichia Corporation, Anan-shi (JP)

(72) Inventor: Hiroaki KAGEYAMA, Tokushima-shi (JP)

(21) Appl. No.: 18/956,887

(22) Filed: Nov. 22, 2024

(30) Foreign Application Priority Data
Dec. 26, 2023 (JP) 2023-218839

(51) Int. Cl. H01L 33/00

(52) U.S. Cl. CPC H10H 20/018

(57) ABSTRACT

A method for manufacturing a light-emitting device includes preparing and separating. In the preparing, a stacked body is prepared. The stacked body includes a substrate, a semiconductor layer, and a coating member. The substrate includes first and second surfaces. The second surface includes first and second regions. The separating includes first and second processes. In the first process, the substrate is separated from the semiconductor layer by irradiating the first region with a laser light of a first irradiation intensity. In the second process, the substrate is separated from the coating member by irradiating at least the second region with the laser light of a second irradiation intensity. The second irradiation intensity is lower than the first irradiation intensity. The second process is performed after the first process.

### CROSS-REFERENCE TO RELATED APPLICATIONS

The present application claims priority under 35 U.S.C. § 119 to Japanese Patent Application No. 2023-218839, filed Dec. 26, 2023, the entire contents of which are hereby incorporated by reference.

### BACKGROUND

### 1. Technical Field

Embodiments described herein relate generally to a method for manufacturing a light-emitting device.

### 2. Description of Related Art

It is known that a technique is used, in manufacturing of a light-emitting device, in which a stacked body that includes a substrate and a semiconductor layer formed on the substrate is irradiated with laser light to separate the substrate from the semiconductor layer (for example, Japanese Patent Publication No. 2011-151191). Such a technique is called laser lift-off. In laser lift-off, the interface between the substrate and the semiconductor layer is irradiated with laser light, so that the semiconductor layer can be decomposed at the interface and the substrate can be separated from the semiconductor layer. In manufacturing a light-emitting device using the laser lift-off, it is desirable to improve the production yield by reducing cracks in the semiconductor layer at the time of the separation.

### SUMMARY

One or more embodiments are directed to a method for manufacturing a light-emitting device, with which the production yield can be improved.

A method for manufacturing a light-emitting device according to an embodiment of the invention includes: preparing a stacked body including a substrate, a semiconductor layer, and a coating member, the substrate including a first surface and a second surface opposite to the first surface, the second surface including a first region and a second region outside the first region, the semiconductor layer being in contact with the second surface within the first region, the coating member being in contact with the second surface within the second region, and surrounding an outer periphery of the semiconductor layer; and separating the semiconductor layer and the coating member from the substrate by irradiating the stacked body from a side of the first surface of the substrate with a laser light. The separating includes a first process of separating the semiconductor layer from the second surface of the substrate with the coating member remaining in contact with the second surface, and after the first process, a second process of separating the coating member from the second surface of the substrate. The first process comprises irradiating the first region with a first laser light of a first irradiation intensity, and the second process comprises irradiating at least the second region with a second laser light of a second irradiation intensity lower than the first irradiation intensity.

According to one or more embodiments of the invention, a method for manufacturing a light-emitting device with improved production yield can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 schematically illustrates a plan view of a stacked body employed in a method for manufacturing a light-emitting device according to a first embodiment;

FIG. 2 schematically illustrates a cross-sectional view of the stacked body to describe a process of preparing according to the method for manufacturing the light-emitting device according to the first embodiment;

FIG. 3 schematically illustrates a plan view of the stacked body to describe a process of separating according to the method for manufacturing the light-emitting device according to the first embodiment;

FIG. 4 schematically illustrates a cross-sectional view of the stacked body and tools to describe the process of separating according to the method for manufacturing the light-emitting device according to the first embodiment;

FIG. 5 schematically illustrates a plan view of the stacked body to describe the process of separating according to the method for manufacturing the light-emitting device according to the first embodiment;

FIG. 6 schematically illustrates a cross-sectional view of the stacked body to describe the process of separating according to the method for manufacturing the light-emitting device according to the first embodiment;

FIG. 7 schematically illustrates a plan view of the stacked body to describe the process of separating according to the method for manufacturing the light-emitting device according to the first embodiment;

FIG. 8 schematically illustrates a cross-sectional view of the stacked body and tools to describe the process of separating according to the method for manufacturing the light-emitting device according to the first embodiment;

FIG. 9 schematically illustrates a plan view of the stacked body to describe the process of separating according to the method for manufacturing the light-emitting device according to the first embodiment;

FIG. 10 schematically illustrates a cross-sectional view of the stacked body to describe the process of separating according to the method for manufacturing the light-emitting device according to the first embodiment;

FIG. 11 schematically illustrates a plan view of the stacked body to describe the process of separating according to the method for manufacturing the light-emitting device according to the first embodiment;

FIG. 12 schematically illustrates a cross-sectional view of a coating member and adjacent layers to describe a process of cutting the coating member according to the method for manufacturing the light-emitting device according to the first embodiment;

FIG. 13 schematically illustrates a cross-sectional view of a light-transmitting layer and adjacent layers to describe a process of disposing the light-transmitting layer according to the method for manufacturing the light-emitting device according to the first embodiment;

FIG. 14 schematically illustrates a cross-sectional view of a module piece to describe a process of mounting the module piece according to the method for manufacturing the light-emitting device according to the first embodiment;

FIG. 15 schematically illustrates a cross-sectional view of the light-emitting device according to the first embodiment to describe a process of disposing a light-reflective member according to the method for manufacturing the light-emitting device according to the first embodiment;

FIG. 16 schematically illustrates a plan view of a stacked body employed in a method for manufacturing a light-emitting device according to a second embodiment;

FIG. 17 schematically illustrates a cross-sectional view of the stacked body to describe a process of preparing according to the method for manufacturing the light-emitting device according to the second embodiment;

FIG. 18 schematically illustrates a cross-sectional view of the stacked body and tools to describe a process of separating according to the method for manufacturing the light-emitting device according to the second embodiment;

FIG. 19 schematically illustrates a cross-sectional view of the stacked body and tools to describe the process of separating according to the method for manufacturing the light-emitting device according to the second embodiment; and

FIG. 20 schematically illustrates a cross-sectional view of the light-emitting device according to the second embodiment to describe a process of disposing a light-transmitting layer according to the method for manufacturing the light-emitting device according to the second embodiment.

### DETAILED DESCRIPTION

Embodiments of the invention will now be described with reference to the drawings.

The drawings are schematic or conceptual; and the relationships between the thickness and width of portions, the proportions of sizes among portions, etc., are not necessarily the same as the actual values. The present disclosure, however, encompasses at least the aspects depicted in the drawings. The dimensions and proportions may be illustrated differently among drawings, even when the same portion is illustrated.

In the specification and drawings, components similar to those already described are marked with the same reference numerals; and a detailed description is omitted as appropriate.

For easier understanding of the following description, the arrangements and configurations of the components are described using an XYZ orthogonal coordinate system. The X-axis, the Y-axis, and the Z-axis are orthogonal to each other. The direction in which the X-axis extends is taken as an “X-direction”; the direction in which the Y-axis extends is taken as a “Y-direction”; and the direction in which the Z-axis extends is taken as a “Z-direction”. For easier understanding of the description, the Z-direction in the direction of the arrow is taken as “up/above”, and the opposite direction is taken as “down/below”, but these directions are independent of the direction of gravity. Viewing in an orientation along the Z-direction is called “when viewed in plan”. End views that show only cross sections may be used as cross-sectional views. As used herein, “corresponding” means having a relationship between regions and regions, surfaces and surfaces, members and members, regions and members, surfaces and members, and regions and surfaces that are related to each other.

### First Embodiment

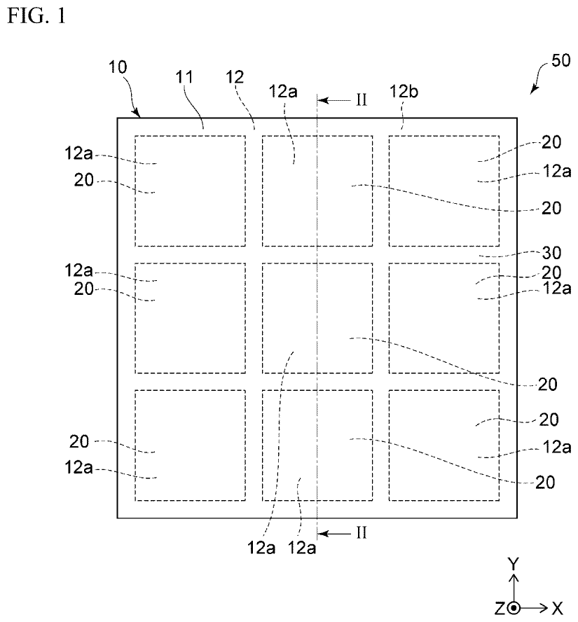

FIG. 1 schematically illustrates a plan view of a stacked body employed in a method for manufacturing a light-emitting device according to a first embodiment.

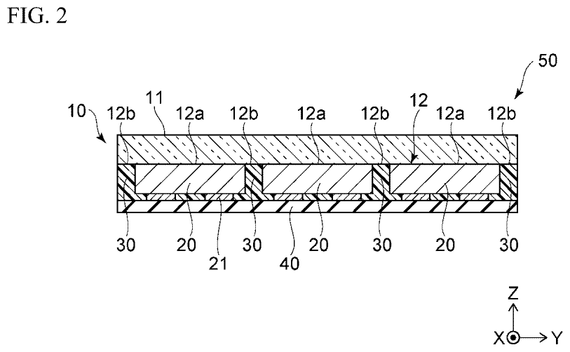

FIG. 2 schematically illustrates a cross-sectional view of the stacked body to describe a process of preparing according to the method for manufacturing the light-emitting device according to the first embodiment.

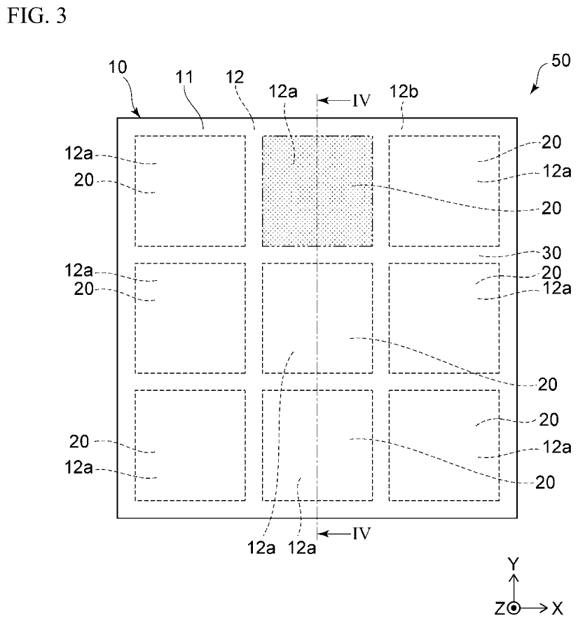

FIGS. 3, 5, 7, 9, and 11 schematically illustrate plan views of the stacked body to describe a process of separating according to the method for manufacturing the light-emitting device according to the first embodiment.

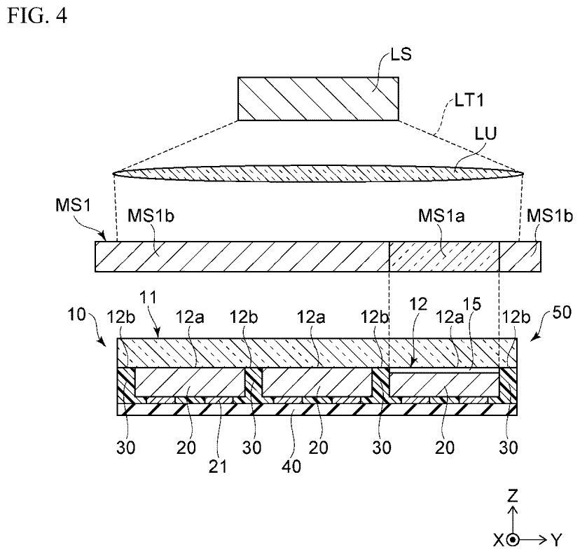

FIGS. 4, 6, 8, and 10 schematically illustrate cross-sectional views of the stacked body to describe the process of separating according to the method for manufacturing the light-emitting device according to the first embodiment.

FIG. 12 schematically illustrates a cross-sectional view of a coating member and adjacent layers to describe a process of cutting the coating member according to the method for manufacturing the light-emitting device according to the first embodiment.

FIG. 13 schematically illustrates a cross-sectional view of a light-transmitting layer and adjacent layers to describe a process of disposing the light-transmitting layer according to the method for manufacturing the light-emitting device according to the first embodiment.

FIG. 14 schematically illustrates a cross-sectional view of a module piece to describe a process of mounting the module piece according to the method for manufacturing the light-emitting device according to the first embodiment.

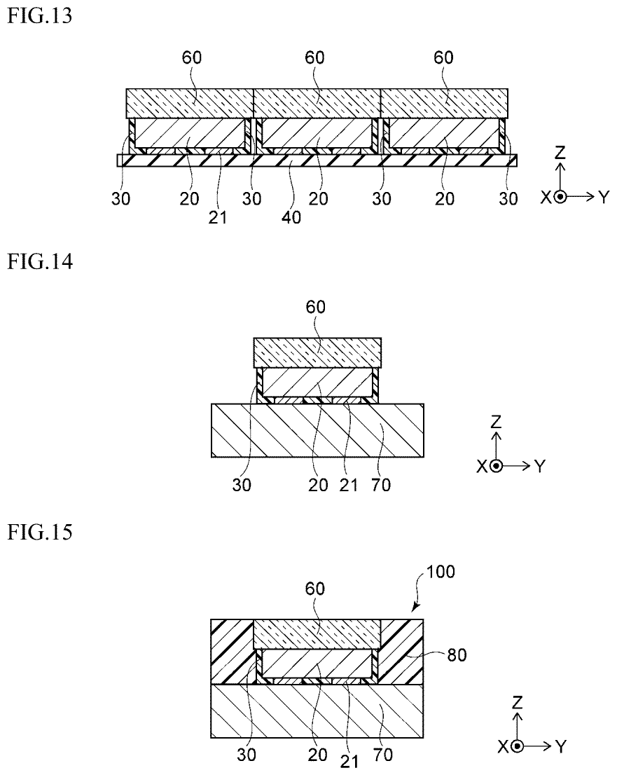

FIG. 15 schematically illustrates a cross-sectional view of the light-emitting device according to the first embodiment to describe a process of disposing a light-reflective member according to the method for manufacturing the light-emitting device according to the first embodiment.

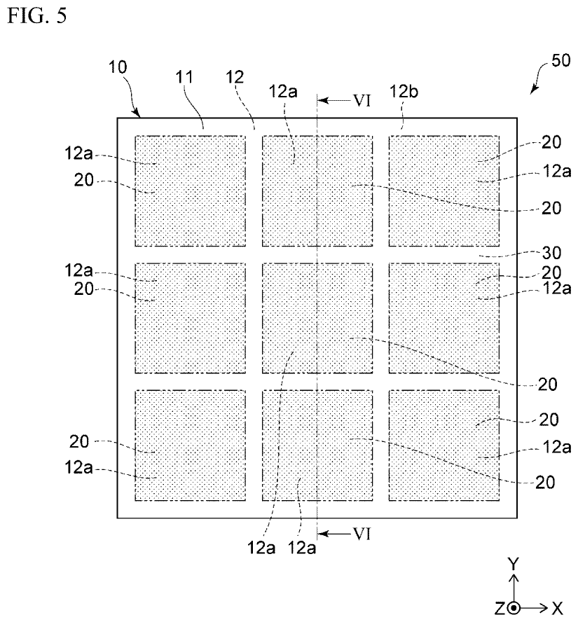

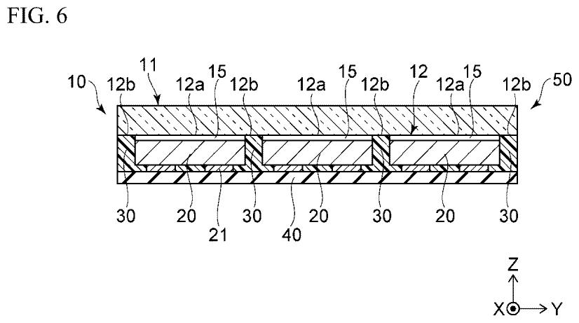

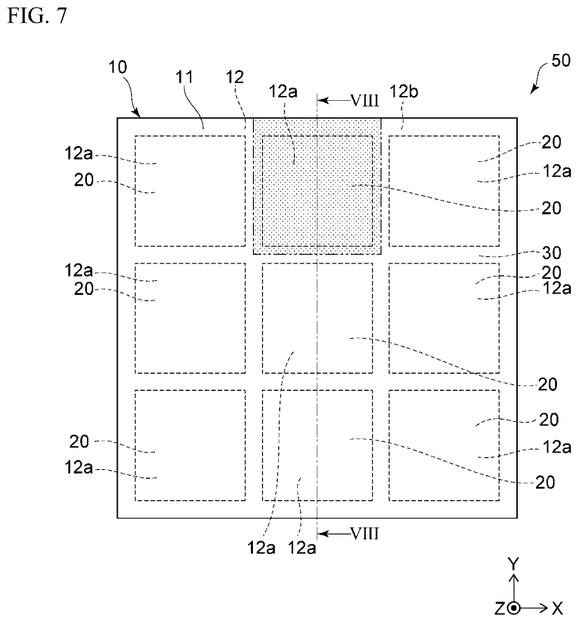

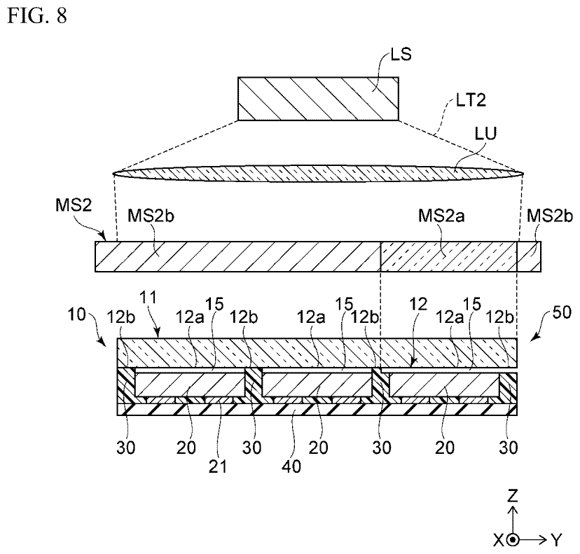

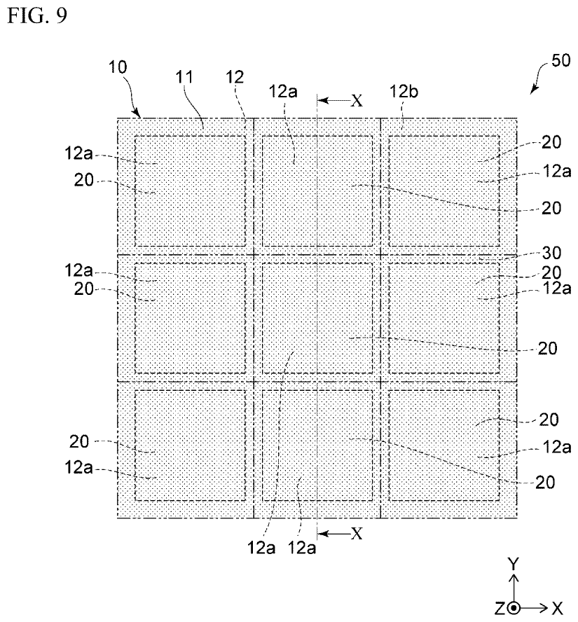

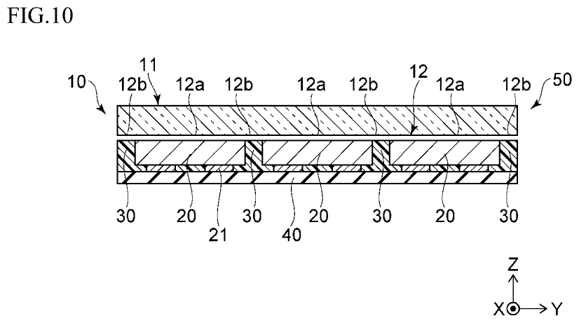

FIG. 2 schematically illustrates a cross-sectional view along line II-II shown in FIG. 1. FIG. 4 schematically illustrates a cross-sectional view along line IV-IV shown in FIG. 3. FIG. 6 schematically illustrates a cross-sectional view along line VI-VI shown in FIG. 5. FIG. 8 schematically illustrates a cross-sectional view along line VIII-VIII shown in FIG. 7. FIG. 10 schematically illustrates a cross-sectional view along line X-X shown in FIG. 9.

As shown in FIGS. 1 to 11, the method for manufacturing the light-emitting device according to the first embodiment includes the process of preparing and the process of separating. Specifically, the method for manufacturing the light-emitting device according to the first embodiment includes a process of preparing a stacked body including a substrate, a semiconductor layer, and a coating member; and a process of separating the substrate from the semiconductor layer and the coating member. The substrate includes a first surface and a second surface opposite to the first surface. The second surface includes a first region and a second region located outside the first region. The semiconductor layer is disposed in the first region. The coating member is disposed in the second region, coats the second region, and surrounds the outer periphery of the semiconductor layer when viewed in plan. The substrate is separated from the semiconductor layer and the coating member by irradiating the stacked body from a side of the first surface of the substrate with a laser light. The process of separating includes a first process of separating the substrate from the semiconductor layer by irradiating the first region with the laser light of a first irradiation intensity, and a second process of separating the substrate from the coating member by irradiating at least the second region with the laser light of a second irradiation intensity lower than the first irradiation intensity. The second process is performed after the first process. As described above, the process of separating is performed after the process of preparing. Accordingly, when the substrate is separated from the semiconductor layer, the stress applied to the semiconductor layer can be reduced since the substrate has not been separated from the coating member. As a result, the possibility of cracking of the semiconductor layer can be reduced in the process of separating. Therefore, a method for manufacturing a light-emitting device, with which the yield can be improved can be provided.

### Process of Preparing

As shown in FIGS. 1 and 2, in the process of preparing, a stacked body 50 is prepared. The stacked body 50 includes a substrate 10, a semiconductor layer 20, and a coating member 30. The semiconductor layer 20 and the coating member 30 are stacked on the substrate 10. The substrate 10 includes a first surface 11 and a second surface 12. The second surface 12 is opposite to the first surface 11. The first surface 11 and the second surface 12 are surfaces perpendicular to the Z-direction. The stacked body 50 can include an electrode 21 on a surface of the semiconductor layer 20 opposite to a surface of the semiconductor layer 20 on which the substrate 10 is disposed.

The second surface 12 includes a first region 12a and a second region 12b. The second region 12b is located outside the first region 12a when viewed in plan. The second region 12b surrounds the first region 12a when viewed in plan. The semiconductor layer 20 is disposed in the first region 12a. The first region 12a is a region, of the second surface 12, which is in contact with the semiconductor layer 20. The coating member 30 is disposed in the second region 12b. The second region 12b is a region, of the second surface 12, which is in contact with the coating member 30. The coating member 30 coats the second region 12b. The coating member 30 surrounds the outer periphery of the semiconductor layer 20 when viewed in plan.

The number of semiconductor layers 20 disposed on one substrate 10 may be one or more. When the stacked body 50 includes a plurality of semiconductor layers 20, the plurality of semiconductor layers 20 are arranged so as to be separated from each other when viewed in plan. In the example shown in FIGS. 1 to 15, in the stacked body 50, nine semiconductor layers 20 are arranged in a matrix on one substrate 10. In the example shown in FIGS. 1 to 15, three semiconductor layers 20 are arranged in the X-direction, and three semiconductor layers 20 are arranged in the Y-direction.

When the stacked body 50 includes a plurality of semiconductor layers 20, the second surface 12 of the substrate 10 includes a plurality of first regions 12a respectively corresponding to the plurality of semiconductor layers 20. When the stacked body 50 includes a plurality of semiconductor layers 20, the region of the second surface 12 other than the plurality of first regions 12a corresponds to the second region 12b.

The stacked body 50 may be prepared by purchase or by fabrication. When the stacked body 50 is prepared by fabrication, the process of preparing includes, for example, a process of forming the semiconductor layer 20 in the first region 12a of the substrate 10 and a process of forming the coating member 30 in the second region 12b of the substrate 10. The process of preparing may include a process of forming the semiconductor layer 20 in the first region 12a and the second region 12b of the substrate 10, a process of removing the semiconductor layer 20 formed in the second region 12b of the substrate 10, and then a process of forming the coating member 30 in the second region 12b of the substrate 10. The process of preparing may include a process of preparing a structure in which the semiconductor layer 20 is disposed in the first region 12a and the second region 12b of the substrate 10 by purchase, a process of removing the semiconductor layer 20 disposed in the second region 12b of the substrate 10, and then a process of forming the coating member 30 in the second region 12b of the substrate 10.

### Process of Separating

As shown in FIGS. 3 to 11, in the process of separating, the substrate 10 is separated from the semiconductor layer 20 and the coating member 30 by irradiating the stacked body 50 from the first surface 11 side of the substrate 10 with laser lights LT1 and LT2. In FIGS. 3, 5, 7, and 9, the region irradiated with the laser light is shown by dot hatching surrounded by a two-dot chain line. The process of separating includes a first process and a second process. The second process is performed after the first process.

As shown in FIGS. 3 and 4, in the first process, the substrate 10 is separated from the semiconductor layer 20 by selectively irradiating the first region 12a from the first surface 11 side with the laser light LT1 of a first irradiation intensity. In the first process, a region including the semiconductor layer 20 when viewed in plan may be also irradiated with the laser light LT1. In the first process, the first region 12a may be irradiated with the laser light LT1 of the first irradiation intensity, or in addition to the first region 12a, a part of the second region 12b (for example, a region corresponding to at least a part of the coating member 30 surrounding the outer periphery of one semiconductor layer 20 when viewed in plan) may be irradiated with the laser light LT1. When the part of the second region 12b is also irradiated with the laser light LT1 in the first process, it is preferable that the width of the region of the second region 12b irradiated with the laser light LT1 in the first process be not more than 1/20 of the width of the coating member 30 (that is, the width between the adjacent two semiconductor layers 20). Accordingly, it is possible to prevent the substrate 10 from completely separating from the coating member 30 in the first process.

As shown in FIGS. 5 and 6, the first process is performed, for example, for all of the first regions 12a (that is, all of the semiconductor layers 20 included in the stacked body 50). In the first process, the irradiation with the laser light LT1 may be performed sequentially for each first region 12a from one end side to the other end side in the Y-direction, or all of the first regions 12a may be simultaneously irradiated with the laser light LT1 at the same time. The irradiation with the laser light LT1 may be performed sequentially for each of a plurality of groups of first regions 12a.

In the first process, the irradiation with the laser light LT1 is performed from the first surface 11 side of the substrate 10, and the laser light LT1 passes through the substrate 10 and reaches the vicinity of the interface between the substrate 10 and the semiconductor layer 20 (that is, the surface where the first region 12a of the second surface 12 of the substrate 10 and the semiconductor layer 20 are in contact with each other). For example, when the semiconductor layer 20 is a gallium nitride compound semiconductor, the gallium nitride existing in the vicinity of the interface between the substrate 10 and the semiconductor layer 20 is decomposed into metallic gallium and nitrogen gas by the laser light LT1, and accordingly, the substrate 10 can physically be separated from the semiconductor layer 20. As a result, the semiconductor layer 20 and the substrate 10 are physically separated from each other with a gap 15 therebetween. Since the coating member 30 that is not irradiated with the laser light LT1 is kept in contact with the substrate 10, gaps 15 formed between the respective semiconductor layers 20 and the substrate 10 exist so as to be separated from each other.

As shown in FIGS. 7 and 8, in the second process, the substrate 10 is separated from the coating member 30 by irradiating at least the second region 12b with the laser light LT2 of a second irradiation intensity lower than the first irradiation intensity. In the second process, at least a part of the coating member 30 surrounding the outer periphery of one semiconductor layer 20 is irradiated with the laser light LT2 when viewed in plan. In the second process, for example, the coating member 30 surrounding the outer periphery of one semiconductor layer 20 can be irradiated with the laser light LT2. When a part of the coating member 30 surrounding the outer periphery of the semiconductor layer 20 (an irradiated region) is irradiated with the laser light LT1 in the first process, a region including the irradiated region may be irradiated with the laser light LT2, or a region that does not include the irradiated region may be irradiated with the laser light LT2 in the second process.

As shown in FIGS. 9 and 10, the second process is performed, for example, for the entire second region 12b. In the second process, the irradiation with the laser light LT2 may be performed sequentially for each second region 12b surrounding the first region 12a from one end side to the other end side in the Y-direction, or the entire second region 12b may be irradiated with the laser light LT2 at a time.

In the example shown in FIGS. 7 to 10, in the second process, the first region 12a and the second region 12b are irradiated with the laser light LT2. In the second process, however, the first region 12a need not be irradiated with the laser light LT2.

In the second process, the irradiation with the laser light LT2 is performed from the first surface 11 side of the substrate 10, and the laser light LT2 passes through the substrate 10 and reaches the vicinity of the interface between the substrate 10 and the coating member 30 (that is, the surface where the second region 12b of the second surface 12 of the substrate 10 and the coating member 30 are in contact with each other). For example, when the coating member 30 includes a resin, the resin included in the coating member 30 is thermally decomposed by heat caused by the laser light LT2. As a result, the substrate 10 can be separated from the coating member 30.

In the process of separating, the second irradiation intensity of the laser light LT2 used in the irradiation in the second process is lower than the first irradiation intensity of the laser light LT1 used in the irradiation in the first process. The second irradiation intensity is preferably not less than ⅛ of the first irradiation intensity and not more than ¼ of the first irradiation intensity. As a result, for example, when the coating member 30 includes a resin, it is possible to reduce excessive thermal decomposition of the resin included in the coating member 30, so that the substrate 10 and the coating member 30 can be successfully separated. As will be described below, when the coating member 30 is composed of a resin including titanium oxide, with irradiation of the coating member 30 with the laser light, the titanium oxide absorbs the laser light and generates heat, and the resin is thermally decomposed accordingly. The titanium oxide may be blackened by absorbing the laser light. The second irradiation intensity described above can reduce blackening of the coating member 30 due to the blackening of the titanium oxide in the second process. The first irradiation intensity is expressed in terms of energy per unit area (MW/cm²). The first irradiation intensity is, for example, not less than 40 MW/cm² and not more than 80 MW/cm². The second irradiation intensity is, for example, not less than 5 MW/cm² and not more than 15 MW/cm².

When the first process is performed, the substrate 10 is separated from the semiconductor layer 20, and the nitrogen gas generated when the semiconductor layer 20 is decomposed by irradiation with the laser light LT1 is trapped in the gap 15. When the second process is performed, the substrate 10 is separated from the coating member 30, and a gap is generated between the coating member 30 and the substrate 10. Therefore, by performing the second process after the first process, the substrate 10 can be separated from the semiconductor layer 20 and the coating member 30 as shown in FIG. 10. At this time, the adjacent gaps 15 are connected to each other, and the nitrogen gas can be released to the outside. Accordingly, the possibility of cracking of the semiconductor layer 20 can be reduced in the process of separating.

Masks can be used for making the region irradiated with the laser light LT1 in the first process and the region irradiated with the laser light LT2 in the second process differ. In the example shown in FIGS. 3 to 10, in the first process, a first mask MS1 is prepared, and the stacked body 50 is irradiated with the laser light LT1 through the first mask MS1. In the second process, a second mask MS2 is prepared, and the stacked body 50 is irradiated with the laser light LT2 through the second mask MS2. The first mask MS1 and the second mask MS2 are disposed on the side of the stacked body 50 irradiated with the laser lights LT1 and LT2, respectively. The laser lights LT1 and LT2 are emitted from, for example, a laser light irradiation device LS. For example, the first mask MS1 and the second mask MS2 are disposed between the laser light irradiation device LS and the stacked body 50.

The first mask MS1 includes a first light-transmitting portion MSla and a first light-shielding portion MS1b. The first light-transmitting portion MSla includes a portion corresponding to one first region 12a. The first light-transmitting portion MSla transmits the laser light LT1. The first light-shielding portion MS1b is located outside the first light-transmitting portion MSla. The first light-shielding portion MS1b blocks the laser light LT1. In the example shown in FIG. 4, the first mask MS1 includes a light-shielding plate including a through hole and a light-transmitting plate disposed in the through hole. In this case, the light-shielding plate corresponds to the first light-shielding portion MS1b, and the light-transmitting plate corresponds to the first light-transmitting portion MSla. However, the configuration is not limited to this, and the through hole of the light-shielding plate may include no plate therein. In this case, the through hole corresponds to the first light-transmitting portion MS1a. Alternatively, the first mask MS1 may be composed of a light-shielding plate including a through hole and a light-transmitting plate disposed over or under the light-shielding plate and covering the through hole of the light-shielding plate. In this case, the light-shielding plate corresponds to the first light-shielding portion MS1b, and the region, in the light-transmitting plate, corresponding to the through hole of the light-shielding plate corresponds to the first light-transmitting portion MSla. The number of through holes of the light-shielding plate may be one or more.

A plurality of light-shielding films for blocking the laser light LT1 may or may not be disposed on the upper surface or the lower surface of the first light-transmitting portion MS1a of the light-transmitting plate. When the plurality of light-shielding films are disposed on the upper surface or the lower surface of the first light-transmitting portion MS1a of the light-transmitting plate, for example, when viewed in plan, a plurality of first light-shielding films can be arranged in a first outer peripheral region of the first light-transmitting portion MS1a of the light-transmitting plate, and a plurality of second light-shielding films can be arranged in a first central region located closer to the center than the first outer peripheral region of the first light-transmitting portion MS1a of the light-transmitting plate. In this case, it is preferable to make the interval between the adjacent second light-shielding films wider than the interval between the adjacent first light-shielding films. In the first process, when a region of the substrate 10 corresponding to the first outer peripheral region (hereinafter may be referred to as “second outer peripheral region”) and a region of the substrate 10 corresponding to the first central region (hereinafter may be referred to as “second central region”) are irradiated with the laser light LT1 of the same irradiation intensity, the separation of the substrate 10 in the second outer peripheral region may occur before the separation of the substrate 10 in the second central region. Therefore, by making the interval between the adjacent second light-shielding films wider than the interval between the adjacent first light-shielding films, the irradiation intensity of the laser light LT1 with which the second central region is irradiated is made higher than the irradiation intensity of the laser light LT1 with which the second outer peripheral region is irradiated, and accordingly, the separation of the substrate 10 in the second central region can be accelerated and the separation of the substrate 10 in the second outer peripheral region can be relatively delayed. Accordingly, the gap between the timing of the separation of the substrate 10 in the second central region and the timing of the separation of the substrate 10 in the second outer peripheral region can be reduced. As a result, the possibility that the semiconductor layer 20 cracks when the substrate 10 is separated can be reduced. The first light-shielding films and the second light-shielding films are, for example, circular when viewed in plan.

The second mask MS2 includes a second light-transmitting portion MS2a and a second light-shielding portion MS2b. The second light-transmitting portion MS2a includes at least a portion corresponding to the second region 12b. The second light-transmitting portion MS2a transmits the laser light LT2. The second light-shielding portion MS2b is located outside the second light-transmitting portion MS2a. The second light-shielding portion MS2b blocks the laser light LT2. In the example shown in FIG. 8, the second mask MS2 includes a light-shielding plate including a through hole and a light-transmitting plate disposed in the through hole. In this case, the light-shielding plate corresponds to the second light-shielding portion MS2b, and the light-transmitting plate corresponds to the second light-transmitting portion MS2a. The configuration is not limited to this, and the through hole of the light-shielding portion may include no plate therein. In this case, the through hole corresponds to the second light-transmitting portion MS2a. The second mask MS2 may be composed of a light-shielding plate including a through hole and a light-transmitting plate disposed over or under the light-shielding plate and covering the through hole of the light-shielding plate. In this case, the light-shielding plate corresponds to the second light-shielding portion MS2b, and the region, in the light-transmitting plate, corresponding to the through hole of the light-shielding plate corresponds to the second light-transmitting portion MS2a. The number of through holes of the light-shielding plate may be one or more.

In the example shown in FIG. 8, in the second process, the first region 12a and the second region 12b are irradiated with the laser light LT2. With the laser light LT2 used in the irradiation of the second region 12b, the entire area of the coating member 30 located on the +Y-direction side of the semiconductor layer 20 irradiated with the laser light LT2 is irradiated. Further, with the laser light LT2 used in the irradiation of the second region 12b, the area of the coating member 30, from the edge of the semiconductor layer 20 on the −Y-direction side to any position (e.g., midpoint) between the semiconductor layer 20 and another adjacent semiconductor layer 20, located on the −Y-direction side of the semiconductor layer 20 irradiated with the laser light LT2 is irradiated. Therefore, the second light-transmitting portion MS2a includes a portion corresponding to the entire area of the coating member 30 located on the +Y-direction side of the semiconductor layer 20 irradiated with the laser light LT2 and a portion corresponding to the area of the coating member 30, from the edge of the semiconductor layer 20 on the −Y-direction side to any position (e.g., midpoint) between the semiconductor layer 20 and another adjacent semiconductor layer 20, located on the −Y-direction side of the semiconductor layer 20 irradiated with the laser light LT2. The outer shape of the second light-transmitting portion MS2a is larger than the outer shape of the first light-transmitting portion MS1a when viewed in plan. When the first region 12a is not irradiated with the laser light LT2 in the second process, the second light-shielding portion MS2b includes a portion corresponding to the first region 12a.

By using the first mask MS1 in the first process and the second mask MS2 in the second process, the region irradiated with the laser light LT1 in the first process and the region irradiated with the laser light LT2 in the second process can be easily made different.

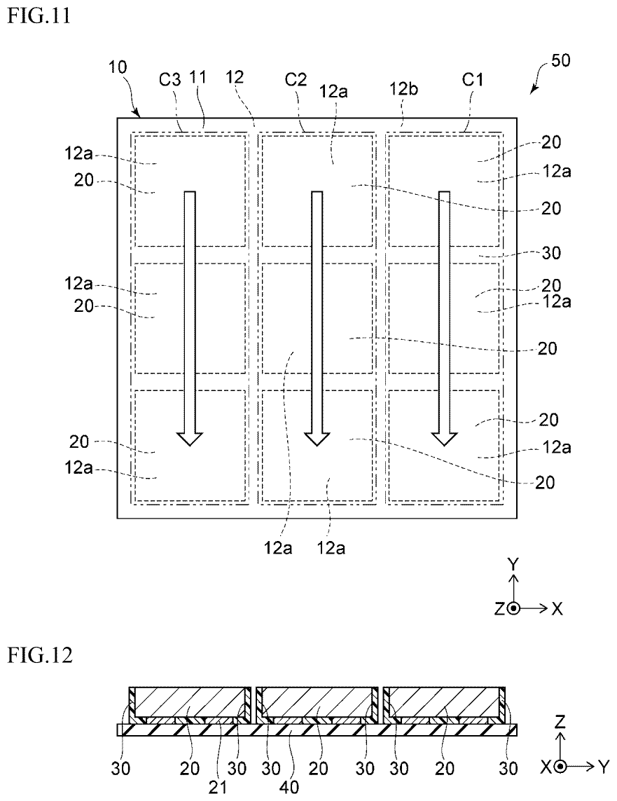

As described above, the stacked body 50 includes, for example, a plurality of semiconductor layers 20. The plurality of semiconductor layers 20 are arranged, for example, in a plurality of columns. In the example shown in FIG. 11, the plurality of semiconductor layers 20 are arranged in three columns, namely, column C1, column C2, and column C3, in the Y-direction. Three semiconductor layers 20 are disposed in each of columns C1, C2, and C3. Column C2 is located between column C1 and column C3 in the X-direction. Columns C1 and C3 are columns located at both ends, and column C2 is a column located at other than both ends.

The process of separating each semiconductor layer 20 can be performed for columns C1, C2, and C3 in any appliable order. For example, the process of separating each semiconductor layer 20 can be performed in the −X-direction, that is, in the order of column C1, column C2, and column C3. It is preferable, however, to perform the process of separating the semiconductor layers 20 arranged in the columns located at both ends after the process of separating the semiconductor layers 20 arranged in the column located at other than both ends, that is, in the order of column C2, column C1, and column C3. Upon irradiation of the stacked body 50 with the laser lights LT1 and LT2, a fixing member can be disposed in order to fix the position of the stacked body 50. By performing the process of separating the semiconductor layers 20 arranged in the columns located at both ends after the process of separating the semiconductor layers 20 arranged in the column located at other than both ends, it is possible to reduce a displacement of the stacked body 50 in the −X-direction with respect to the fixing member. In each column, the process of separating can be performed in order from one end side to the other end side in the Y-direction (that is, in the order indicated by the white arrow in FIG. 11).

When there are four or more columns, for example, the process of separating is performed from a column located at other than both ends and is subsequently performed up to the column located farthest in the −X-direction side in order. Thereafter, the process of separating can performed in the −X-direction from the column located farthest on the +X-direction side. However, the process of separating is not limited to this, and the process of separating may be performed in the −X-direction from the column located at the end on the +X-direction side to the column located farthest on the −X-direction side in order. The process of separating may be performed in the +X-direction from the column located at the end on the −X-direction side to the column located farthest on the +X-direction side in order.

After the first process on one semiconductor layer 20 (first semiconductor layer), the second process may be performed on the coating member 30 surrounding the outer periphery of this semiconductor layer 20 (first semiconductor layer). Then, after the first process on another semiconductor layer 20 (second semiconductor layer), the second process may be performed on the coating member 30 surrounding the outer periphery of this semiconductor layer 20 (second semiconductor layer).

In the example shown in FIGS. 7 to 8, in the second process, upon irradiation of the coating member 30 surrounding the outer periphery of one of the two adjacent semiconductor layers 20 with the laser light LT2, a part (for example, half) of the coating member 30 located between the two semiconductor layers 20 is irradiated with the laser light LT2. Then, upon irradiation of the coating member 30 surrounding the outer periphery of the other semiconductor layer 20 with the laser light LT2, the remaining part (for example, the other half) of the coating member 30 located between the two semiconductor layers 20 is irradiated with the laser light LT2. Accordingly, the entire area of the coating member 30 located between the two semiconductor layers 20 is irradiated with the laser light LT2. In the second process, upon irradiation of the coating member 30 surrounding the outer periphery of one of the two adjacent semiconductor layers 20, the entire area of the coating member 30 located between the two semiconductor layers 20 may be irradiated with the laser light LT2, and also upon irradiation of the coating member 30 surrounding the outer periphery of the other semiconductor layer 20, the entire area of the coating member 30 located between the two semiconductor layers 20 may be irradiated with the laser light LT2. That is, in the second process, the coating member 30 located between the two semiconductor layers 20 may be irradiated with the laser light LT2 a plurality of times. In the second process, upon irradiation of the coating member 30 surrounding the outer periphery of one of the two adjacent semiconductor layers 20 with the laser light LT2, the coating member 30 located between the two semiconductor layers 20 may not be irradiated with the laser light LT2, and upon irradiation of the coating member 30 surrounding the outer periphery of the other semiconductor layer 20, the entire area of the coating member 30 located between the two semiconductor layers 20 may be irradiated with the laser light LT2.

The substrate 10, the semiconductor layer 20, and the coating member 30 constituting the stacked body 50 will be described.

### Substrate

The substrate 10 is a member on which the semiconductor layer 20 and the coating member 30 are stacked. The substrate 10 can transmit the laser lights LT1 and LT2, for example. The substrate 10 includes, for example, at least any of sapphire and glass. The shape of the substrate 10 is, for example, a flat plate shape. As used herein, the “flat plate shape” need to be a substantially plate shape, and may be a plate whose surface is corrugated or has fine irregularities.

### Semiconductor Layer

The semiconductor layer 20 includes, for example, an n-type semiconductor layer, a p-type semiconductor layer, and a light-emitting layer. The light-emitting layer is positioned between the n-type semiconductor layer and the p-type semiconductor layer. The light-emitting layer may have a structure such as a double heterojunction, single quantum well (SQW), etc., or may have a structure of one light-emitting layer group such as a multi-quantum well (MQW). The light emission peak wavelength of the light-emitting layer can be appropriately selected according to the purpose. For example, the light-emitting layer can be configured to emit visible light (e.g., approximately a wavelength range of 400 to 700 nm) or ultraviolet light (e.g., approximately a wavelength range of 100 to 400 nm). The semiconductor stacked body that includes such a light-emitting layer includes, for example, all of the compositions of semiconductors of the chemical formula InₓAl_{y}Ga_{1-x-y}N (0≤x, 0≤y, and x+y≤1) for which the composition ratios x and y are changed within their respective ranges.

The semiconductor layer 20 may have a structure including one or more light-emitting layers between the n-type semiconductor layer and the p-type semiconductor layer, or may have stack of structures each of which includes an n-type semiconductor layer, a light-emitting layer, and a p-type semiconductor layer in this order. When the semiconductor layer 20 includes multiple light-emitting layers, the multiple light-emitting layers may include light-emitting layers having different light emission peak wavelengths, or may include light-emitting layers having the same light emission peak wavelength. The light emission peak wavelength being the same also includes cases where there is a variation within ±10 nm. The combination of the light emission peak wavelengths of the multiple light-emitting layers can be selected as appropriate. For example, when the semiconductor layer 20 includes two light-emitting layers, the light-emitting layers can be selected in any of the combinations of blue light and blue light, green light and green light, red light and red light, ultraviolet light and ultraviolet light, blue light and ultraviolet light, blue light and green light, blue light and red light, green light and red light, etc. Each light-emitting layer may include multiple active layers having different light emission peak wavelengths, or multiple active layers having the same light emission peak wavelength.

The semiconductor layer 20 is, for example, rectangular when viewed in plan. The length of one side of the semiconductor layer 20 when viewed in plan is, for example, not less than 200 μm and not more than 2,000 μm.

### Coating Member

The coating member 30 is a member for holding the semiconductor layer 20. When the stacked body 50 includes a plurality of semiconductor layers 20, the coating member 30 can connect the adjacent semiconductor layers 20 by coating the side surfaces of the semiconductor layer 20 and the second region 12b of the substrate 10. Accordingly, when the substrate 10 is separated from the semiconductor layer 20, the coating member 30 can retain each semiconductor layer 20. The coating member 30 includes, for example, a resin and a light-reflective material. The resin is, for example, a silicone resin, an epoxy resin, a polyimide resin, or a modified resin thereof. The light-reflective material is, for example, titanium oxide, aluminum oxide, or silicon oxide. As the light-reflective material, titanium oxide is preferable because it is relatively stable with moisture etc. and has a high refractive index. Since the coating member 30 includes a resin and a light-reflective material, the coating member 30 can be used as a light-reflective member of the light-emitting device. The coating member 30 may not include a light-reflective material and may be composed only of a resin.

The stacked body 50 can further include a support body 40. The support body 40 supports the semiconductor layer 20 and the coating member 30. The support body 40 is disposed on a surface of the semiconductor layer 20 and the coating member 30 opposite to the substrate 10. That is, each of the semiconductor layer 20 and the coating member 30 is located between the substrate 10 and the support body 40. As the material of the support body 40, for example, a resin (for example, polyolefin or polyimide), metal, glass, sapphire, or silicon can be used. The thickness of the support body 40 is, for example, not less than 70 μm and not more than 200 μm.

### Laser Light

As the laser light irradiation device LS, a gas laser or a solid-state laser can be used. As the gas laser, for example, an excimer laser can be used. The laser light irradiation device LS emits, for example, pulsed laser lights LT1 and LT2. In this case, the pulse width is, for example, 20 nsec. The emission peak wavelength of the laser lights LT1 and LT2 is, for example, 248 nm. For example, the laser lights LT1 and LT2 can be emitted from the laser light irradiation device LS, and can reach the stacked body 50 by passing through a lens LU and the first mask MS1 or the second mask MS2. A top-hat laser beam in which the irradiation intensity distribution of the laser light is substantially uniform can be used as the laser lights LT1 and LT2.

### Process of Cutting Coating Member 30

The method for manufacturing the light-emitting device according to the first embodiment can further include the process of cutting the coating member 30.

As shown in FIG. 12, in the process of cutting the coating member 30, the coating member 30 between the semiconductor layers 20 adjacent to each other is cut. For example, when there is one semiconductor layer 20 included in the stacked body 50, the process of cutting can be omitted.

### Process of Disposing Light-Transmitting Layer 60

The method for manufacturing the light-emitting device according to the first embodiment can further include the process of disposing a light-transmitting layer 60. The process of disposing the light-transmitting layer 60 is performed, for example, after the process of separating.

As shown in FIG. 13, in the process of disposing the light-transmitting layer 60, the light-transmitting layer 60 is disposed on the surface of the semiconductor layer 20 on the side where the substrate 10 is separated. The light-transmitting layer 60 includes, for example, a fluorescer. As the fluorescer, a known fluorescer is used. In combination with each fluorescer, a light-emitting device that emits light of a desired color can be configured. For example, when the light emitted by the semiconductor layer 20 is blue light and the fluorescer is an yttrium, aluminum, garnet-based fluorescer (hereinafter referred to as “YAG fluorescer”) that converts blue light into yellow light, the blue light emitted by the semiconductor layer 20 and the yellow light wavelength-converted by the YAG fluorescer are mixed, thereby producing white light from the light-emitting device. The light-transmitting layer 60 is disposed on the surface of the semiconductor layer 20 on the side where the substrate 10 is separated, for example, with an adhesive member therebetween. The shape of the light-transmitting layer 60 is, for example, a flat plate shape.

### Process of Mounting Module Piece

The method for manufacturing the light-emitting device according to the first embodiment can further include the process of mounting a module piece including one semiconductor layer 20.

As shown in FIG. 14, in the process of mounting the module piece, the module piece including the semiconductor layer 20 is mounted so that the surface of the semiconductor layer 20 opposite to the surface separated from the substrate 10 faces a wiring substrate 70. In the example shown in FIG. 14, the module piece including one semiconductor layer 20, with the light-transmitting layer 60 and the dissected coating member 30 is mounted on the wiring substrate 70. In the example shown in FIG. 14, the module piece including one semiconductor layer 20 is mounted on the wiring substrate 70. However, the mounting is not limited to this, and a module piece including a plurality of semiconductor layers 20 may be mounted on the wiring substrate 70. When a module piece including a plurality of semiconductor layers 20 are mounted on the wiring substrate 70, the coating member 30 that coats the side surface of one of the adjacent semiconductor layers 20 may be separated from the coating member 30 that coats the side surface of the other semiconductor layer 20. Alternatively, the coating member 30 that coats the side surface of one of the adjacent semiconductor layers 20 may be connected to the coating member 30 that coats the side surface of the other semiconductor layer 20.

### Wiring Substrate

The wiring substrate 70 includes, for example, a base member and a wiring part disposed on the base member. The shape of the wiring substrate 70 is, for example, a flat plate shape.

### Process of Disposing Light-Reflective Member 80

The method for manufacturing the light-emitting device according to the first embodiment can further include the process of disposing a light-reflective member 80.

As shown in FIG. 15, in the process of disposing the light-reflective member 80, the light-reflective member 80 is disposed on the side surface of the coating member 30, the side surface of the light-transmitting layer 60, and the surface of the wiring substrate 70 on which the semiconductor layer 20 is mounted.

The process of cutting the coating member 30, the process of disposing the light-transmitting layer 60, the process of mounting the module piece including the semiconductor layer 20, and the process of disposing the light-reflective member 80 described above are performed after the process of separating. In the method for manufacturing the light-emitting device according to the first embodiment, the process of cutting the coating member 30, the process of disposing the light-transmitting layer 60, the process of mounting the module piece including the semiconductor layer 20, and the process of disposing the light-reflective member 80 are performed in this order. However, the order is not limited to this, and the processes may be performed in the order of the process of cutting the coating member 30, the process of mounting the module piece including the semiconductor layer 20, the process of disposing the light-transmitting layer 60, and the process of disposing the light-reflective member 80. At least one of the process of disposing the light-transmitting layer 60 and the process of disposing the light-reflective member 80 can be omitted.

### Light-Reflective Member

The light-reflective member 80 includes, for example, a resin and a light-reflective material. The resin is, for example, a silicone resin, an epoxy resin, a polyimide resin, or a modified resin thereof. The light-reflective material is, for example, titanium oxide, aluminum oxide, or silicon oxide.

As described above, in the method for manufacturing the light-emitting device according to the first embodiment, the light-emitting device 100 is manufactured by the process of preparing, the process of separating, the process of cutting the coating member 30, the process of disposing the light-transmitting layer 60, the process of mounting the module piece including the semiconductor layer 20, and the process of disposing the light-reflective member 80.

### Second Embodiment

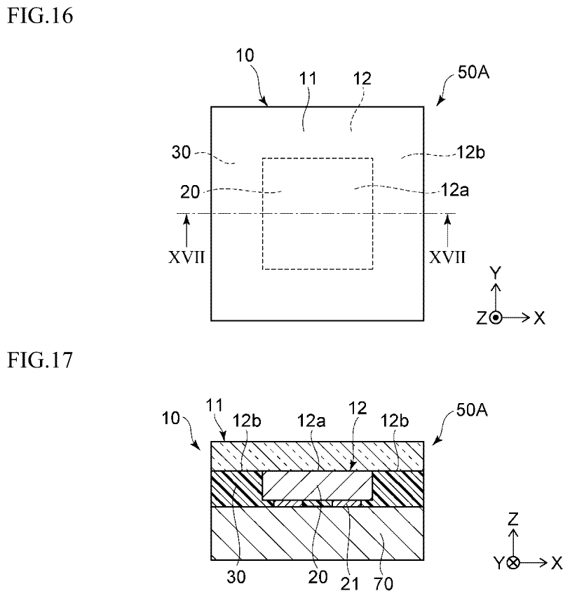

FIG. 16 schematically illustrates a plan view of a stacked body employed in a method for manufacturing a light-emitting device according to a second embodiment.

FIG. 17 schematically illustrates a cross-sectional view of the stacked body to describe a process of preparing according to the method for manufacturing the light-emitting device according to the second embodiment.

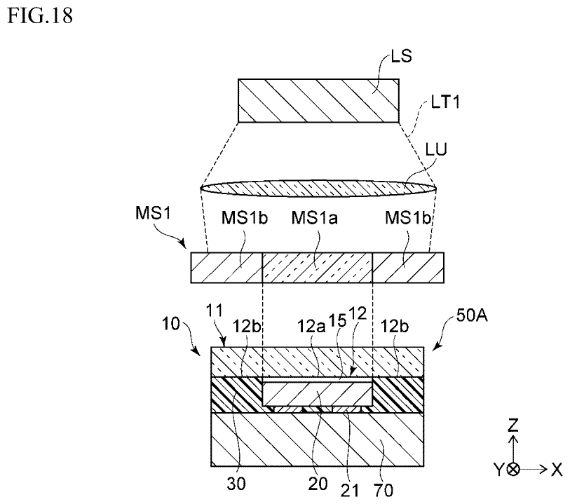

FIG. 18 schematically illustrates a cross-sectional view of the stacked body to describe a process of separating according to the method for manufacturing the light-emitting device according to the second embodiment.

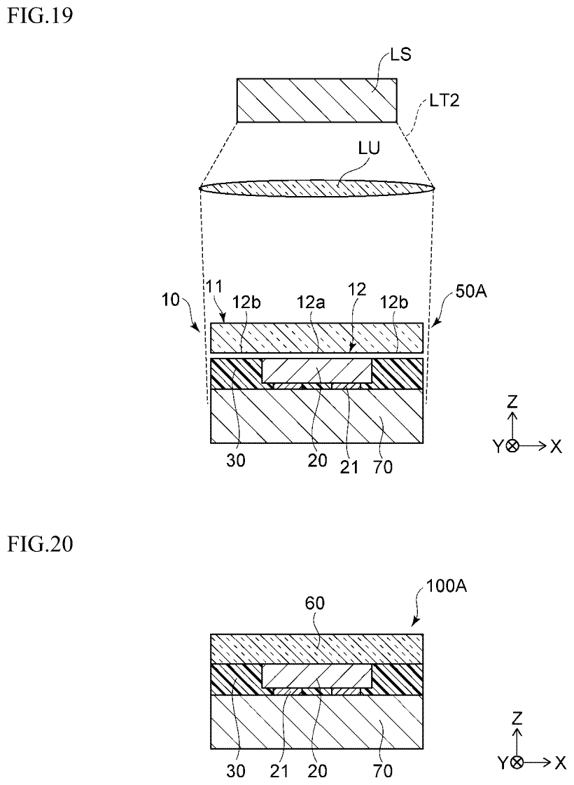

FIG. 19 schematically illustrates a cross-sectional view of the stacked body to describe the process of separating according to the method for manufacturing the light-emitting device according to the second embodiment.

FIG. 20 schematically illustrates a cross-sectional view of the stacked body to describe a process of disposing the light-transmitting layer 60 according to the method for manufacturing the light-emitting device according to the second embodiment.

FIG. 17 schematically illustrates a cross-sectional view along line XVII-XVII shown in FIG. 16. Each of FIGS. 18 to 20 schematically illustrates a cross-sectional view corresponding to the position of line XVII-XVII of FIG. 16 in a corresponding process.

As shown in FIGS. 16 to 20, the method for manufacturing the light-emitting device according to the second embodiment is the same as the method for manufacturing the light-emitting device according to the first embodiment, except that a stacked body 50A in which one semiconductor layer 20 is disposed on one substrate 10 is prepared in the process of preparing, the first process and the second process are performed on the stacked body 50A in the process of separating, and the process of separating is performed after the semiconductor layer 20 is mounted on the wiring substrate 70. Therefore, the explanation of the duplicate content may be omitted.

As shown in FIGS. 16 and 17, in the process of preparing of the method for manufacturing the light-emitting device according to the second embodiment, the stacked body 50A including one semiconductor layer 20 is prepared. In the stacked body 50A, the semiconductor layer 20 and the coating member 30 are supported by the wiring substrate 70 instead of the support body 40. That is, in the stacked body 50A, each of the semiconductor layer 20 and the coating member 30 is located between the substrate 10 and the wiring substrate 70.

As shown in FIGS. 18 and 19, in the process of separating of the method for manufacturing the light-emitting device according to the second embodiment, the first process and the second process are performed on the stacked body 50A. In the example shown in FIG. 18, in the first process, the first region 12a is irradiated with the laser light LT1 of the first irradiation intensity by using the first mask MS1 including the first light-transmitting portion corresponding to the first region. In the example shown in FIG. 19, in the second process, the first region 12a and the second region 12b are irradiated with the laser light LT2 of the second irradiation intensity without using a mask (second mask MS2). In the second process, a mask (second mask MS2) may be used.

Advantages similar to those in the method for manufacturing the light-emitting device according to the first embodiment can also be obtained in the method for manufacturing the light-emitting device according to the second embodiment.

In the method for manufacturing the light-emitting device according to the second embodiment, the process of cutting the coating member 30, the process of mounting the module piece including the semiconductor layer 20, and the process of disposing the light-reflective member 80 can be omitted. As shown in FIG. 20, in the method for manufacturing the light-emitting device according to the second embodiment, the process of disposing the light-transmitting layer 60 can be performed after the process of separating.

As described above, in the method for manufacturing the light-emitting device according to the second embodiment, a light-emitting device 100A is manufactured by the process of preparing, the process of separating, and the process of disposing the light-transmitting layer 60.

In the example shown in FIGS. 16 to 20, a case where the process of separating is performed on the stacked body 50A including one semiconductor layer 20 is described. In the method for manufacturing the light-emitting device according to the second embodiment, the process of separating may be performed on the stacked body 50A including a plurality of semiconductor layers 20.

As described above, according to the embodiments, a method for manufacturing a light-emitting device with which the yield can be improved is provided.

The embodiments above are examples embodying the invention; and the invention is not limited to these embodiments. For example, additions, deletions, or modifications of some of the components or processes according to the embodiments above are also included in the invention. The embodiments above can be implemented in combination with each other.

The invention can be favorably used to manufacture an LED, etc.

1. A method for manufacturing a light-emitting device, the method comprising:
preparing a stacked body including a substrate, a semiconductor layer, and a coating member, the substrate including a first surface and a second surface opposite to the first surface, the second surface including a first region and a second region outside the first region, the semiconductor layer being in contact with the second surface within the first region, the coating member being in contact with the second surface within the second region the coating member surrounding an outer periphery of the semiconductor layer; and
separating the semiconductor layer and the coating member from the substrate by irradiating the stacked body from a side of the first surface of the substrate with a laser light,
said separating including
a first process of separating the semiconductor layer from the second surface of the substrate with the surface of the coating member remaining in contact with the second surface, the first process comprising irradiating the first region with a first laser light of a first irradiation intensity, and
after the first process, a second process of separating the coating member from the second surface of the substrate, the second process comprising irradiating at least the second region with a second laser light of a second irradiation intensity lower than the first irradiation intensity.

2. The method according to claim 1, wherein the first region and the second region are irradiated with the second laser light during the second process.

3. The method according to claim 2, wherein
during the first process, the first region is irradiated with the first laser light through a first mask, the first mask including a first light-transmitting portion corresponding to the first region and a first light-shielding portion outside the first light-transmitting portion and corresponding to the second region, and
during the second process, the second region is irradiated with the second laser light through a second mask, the second mask including a second light-transmitting portion having an outer shape larger than an outer shape of the first light-transmitting portion, and a second light-shielding portion outside the second light-transmitting portion.

4. The method according to claim 1, wherein the coating member includes a resin and a light-reflective material.

5. The method according to claim 4, wherein the light-reflective material includes titanium oxide.

6. The method according to claim 1, wherein the second irradiation intensity is not less than ⅛ of the first irradiation intensity and not more than ¼ of the first irradiation intensity.

7. The method according to claim 1, wherein the semiconductor layer comprises an n-type semiconductor layer, a p-type semiconductor layer, and a light-emitting layer between the n-type semiconductor layer and the p-type semiconductor layer.

8. The method according to claim 7, wherein a light emission peak wavelength of the light-emitting layer is longer than a peak wavelength of the first laser light and a peak wavelength of the second laser light.

9. The method according to claim 1, wherein during the first process, a gap is formed between the first region of the second surface and the surface of the semiconductor layer, and nitrogen gas is contained in the gap.

10. The method according to claim 9, wherein during the second process, the nitrogen gas is released out of the gap.

11. A method for manufacturing a light-emitting device, the method comprising:
preparing a stacked body including a substrate, a plurality of semiconductor layers arranged in a matrix, and a coating member, the substrate including a first surface and a second surface opposite to the first surface, the second surface including a plurality of first regions and a second region outside the first regions, each of the semiconductor layers being in contact with the second surface within a corresponding one of the first regions, the coating member being in contact with the second surface within the second region and surrounding an outer periphery of each of the semiconductor layers; and
separating each of the semiconductor layers and the coating member from the substrate by irradiating the stacked body from a side of the first surface of the substrate with a laser light,
said separating including
a first process of separating each of the semiconductor layers from the second surface of the substrate with the surface of the coating member remaining in contact with the second surface, the first process comprising irradiating the first regions with a first laser light of a first irradiation intensity, and
after the first process, a second process of separating the coating member from the second surface of the substrate, the second process comprising irradiating at least the second region with a second laser light of a second irradiation intensity lower than the first irradiation intensity.

12. The method according to claim 11, wherein the first process comprises:
irradiating a first group of the first regions corresponding to a first group of the semiconductor layers with the first laser light; and
after irradiating the first group of the first regions, irradiating a second group of the first regions corresponding to a second group of the semiconductor layers with the first laser light, the second group of the first regions being different from the first group of the first regions.

13. The method according to claim 12, wherein
the first group of the semiconductor layers is first one or more columns of the semiconductor layers in the matrix, and
the second group of the semiconductor layers is second one or more columns of the semiconductor layers in the matrix.

14. The method according to claim 13, wherein the second one or more columns of semiconductor layers in the matrix include outermost columns on both ends of the matrix.

15. The method according to claim 11, wherein the first process comprises:
irradiating a first group of the first regions corresponding to a first column of the semiconductor layers in the matrix with the first laser light; and
after irradiating the first group of the first regions, irradiating a second group of the first regions corresponding to a second column of the semiconductor layers in the matrix with the first laser light; and
after irradiating the second group of the first regions, irradiating a third group of the first regions corresponding to a third column of the semiconductor layers in the matrix with the first laser light.

16. The method according to claim 15, wherein
the second column is an outermost column of the matrix in a first end, and
the third column is an outermost column of the matrix in a second end opposite to the first end.

17. The method according to claim 15, wherein
the first column is an outermost column of the matrix in a first end, and
the third column is an outermost column of the matrix in a second end opposite to the first end.

18. The method according to claim 11, wherein the first process comprises sequentially irradiating the plurality of first regions one by one.

19. The method according to claim 11, wherein the first process comprises simultaneously irradiating the plurality of first regions.

20. The method according to claim 11, wherein the plurality of first regions and the second region are irradiated with the second laser light during the second process.
